(19) United States
(12) Patent Application Publication
(10) Pub. No.: US 2025/0146169 A1
(43) Pub. Date: May 8, 2025

(54) METHOD FOR GROWING GALLIUM OXIDE SINGLE CRYSTAL AND APPARATUS FOR GROWING SINGLE CRYSTAL

(71) Applicant: Korea Institute of Ceramic Engineering and Technology, Jinju-si (KR)

(72) Inventors: Si Young BAE, Jinju-si (KR); Seong Min JEONG, Suwon-si (KR); Yun Ji SHIN, Jinju-si (KR); Tae Hun Gu, Jinju-si (KR); A Ran SHIN, Jinju-si (KR)

(73) Assignee: Korea Institute of Ceramic Engineering and Technology, Jinju-si (KR)

(21) Appl. No.: 18/816,567

(22) Filed: Aug. 27, 2024

(30) Foreign Application Priority Data
Nov. 8, 2023 (KR) 10-2023-0153350

(51) Int. Cl. C30B 9/00; C30B 15/08; C30B 15/10; C30B 15/20; C30B 29/16

(52) U.S. Cl. CPC C30B 9/00; C30B 15/08; C30B 15/10; C30B 15/20; C30B 29/16

(57) ABSTRACT

The present invention relates to a method for growing a gallium oxide single crystal and an apparatus for growing a single crystal, and according to one aspect of the present invention, the method includes providing a gallium oxide raw material in a crucible containing iridium, injecting carbon dioxide so that a preset carbon dioxide partial pressure is formed to suppress the loss of iridium, melting the gallium oxide raw material provided in the crucible, and producing a gallium oxide single crystal from the melt.

### CROSS-REFERENCE TO RELATED APPLICATION

This application claims priority to and the benefit of Korean Patent Application No. 10-2023-0153350, filed on Nov. 8, 2023, the disclosure of which is incorporated herein by reference in its entirety.

### BACKGROUND

### 1. Field of the Invention

The present invention relates to a method for growing a gallium oxide single crystal and an apparatus for growing a single crystal, and more specifically, to a method for growing a gallium oxide single crystal for a semiconductor substrate and an apparatus for growing a single crystal suitable therefor.

### 2. Discussion of Related Art

Power semiconductors, which are semiconductor devices mainly used in power control and power conversion systems, have the characteristics of being able to control high voltage and current, provide high efficiency and stability by minimizing energy loss, and have fast switching speeds, so they are also used for high-frequency power conversion.

β-Ga₂O₃, which is used as a material for power semiconductors, has a wide band gap of about 4.8 eV and a high breakdown field of 8 MV/cm, and shows a Baliga figure of merit (FOM) that is about 4 times that of GaN and about 10 times that of 4H—SiC, and is attracting attention in the field of power semiconductor utilization.

As a method for producing a gallium oxide single crystal, a solution growth method such as edge-defined film-fed growth (EFG), the Czochralski (CZ) method, or floating-zone (FZ) method may be selected. At this time, since gallium oxide melts at a high temperature of 1,700° C. or higher, an expensive crucible with excellent heat resistance and fire resistance should be used as a heating vessel.

An iridium (Ir) crucible is widely used as a heating vessel for growing the gallium oxide single crystal. Iridium is a very rare precious metal contained in the earth's crust at a ratio of about 10 parts per billion (ppb), and is an expensive material.

However, in a high-temperature environment such as a gallium oxide single crystal production process, iridium contained in an iridium crucible may be partially oxidized or form a gallium-iridium alloy, resulting in a loss of iridium. For this reason, there is a problem that the cost of producing the gallium oxide single crystal increases significantly.

Accordingly, there is a need for technology to minimize the loss of iridium during the gallium oxide single crystal growth process using an iridium crucible.

Meanwhile, the foregoing background art is technical information that the inventor has possessed for derivation of the present invention or acquired during the derivation process, and cannot necessarily be referred to as known technology disclosed to the general public prior to filing the present invention.

### RELATED ART DOCUMENTS

### Patent Documents

(Patent Document 1) Korean Patent Registration No. 10-2325007 (2021.11.05)
(Patent Document 2) Korean Patent Registration No. 10-2546042 (2023.06.16)
(Patent Document 3) U.S. Registration Patent No. U.S. Pat. No. 11,674,238 (2023.06.13)

### SUMMARY OF THE INVENTION

One embodiment of the present invention is directed to providing a method for growing a gallium oxide single crystal, which minimizes the loss of iridium metal contained in an iridium crucible, and an apparatus for growing a single crystal.

The problems of the present invention are not limited to the problems mentioned above, and other problems not mentioned will be clearly understood by those skilled in the art from the following description.

As a technical means for achieving the above-described technical problem, according to one aspect of the present invention, a method for growing a gallium oxide single crystal includes providing a gallium oxide raw material in a crucible containing iridium, injecting carbon dioxide so that a preset partial pressure of the carbon dioxide is formed to suppress the loss of the iridium, melting the gallium oxide raw material provided in the crucible, and producing a gallium oxide single crystal from the melt.

According to another aspect of the present invention, the preset partial pressure of the carbon dioxide may be 40% or more and 60% or less.

According to still another aspect, the injecting of the carbon dioxide may include injecting the carbon dioxide at a pressure of less than 2.4 bar.

According to yet another aspect, the injecting of the carbon dioxide may include injecting argon.

According to yet another aspect, the injecting of the argon may include injecting the argon at a pressure of less than 4.5 bar.

According to yet another aspect, after the single crystal growth method is performed once, a mass of the solid iridium metal contained in the crucible may be 99.75% or more of the mass of the solid iridium metal contained in the crucible before the one-time performance.

According to yet another aspect, a mass of the produced gallium oxide single crystal may be 90% or more of the mass of the provided gallium oxide raw material.

According to yet another aspect, after the single crystal growth method is performed once, a mass of the provided gallium oxide raw material remaining in the crucible may be less than 10% of the mass of the gallium oxide raw material provided in the crucible before the one-time performance.

According to yet another aspect, the producing of the gallium oxide single crystal may include producing the gallium oxide single crystal from the melt through any one of EFG and CZ growth.

As a technical means for achieving the above-described technical problem, according to another aspect of the present invention, an apparatus for growing a single crystal includes a crucible, a heating device that heats the crucible, a chamber in which the crucible is accommodated, an injection unit that injects carbon dioxide into the chamber, and a control unit that controls a partial pressure of the injected carbon dioxide.

According to another aspect, the control unit may control the partial pressure of the injected carbon dioxide so that the partial pressure of the carbon dioxide in the chamber is 40% or more and 60% or less.

According to still another aspect of the present invention, the injection unit may inject the carbon dioxide into the chamber at a pressure of less than 2.4 bar.

According to yet another aspect of the present invention, the injection unit may inject argon into the chamber at a pressure of less than 4.5 bar.

According to yet another aspect of the present invention, the apparatus for growing a single crystal may further include a throttle valve.

According to yet another aspect of the present invention, the throttle valve may control the air pressure in the chamber to be more than 1 bar and less than 1.4 bar.

According to yet another aspect of the present invention, the apparatus for growing a single crystal may further include a seed crystal lifting and lowering device for growing the single crystal.

According to yet another aspect of the present invention, the chamber may include a refractory material capable of withstanding high temperatures.

According to yet another aspect of the present invention, the main raw material of the crucible may be iridium.

According to yet another aspect of the present invention, the apparatus for growing a single crystal may further include a die inside the crucible, and a slit inside the die that communicates with the internal space of the crucible.

According to yet another aspect of the present invention, the main raw material of the die may be iridium.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 shows a view for describing an apparatus for growing a single crystal according to one embodiment of the present invention;

FIG. 2 shows a flowchart for explaining a method for growing a gallium oxide single crystal according to one embodiment of the present invention;

FIG. 3 shows a partial cutaway perspective view for explaining the internal structure of a crucible according to one embodiment of the present invention;

FIG. 4 shows a perspective view for explaining the step of producing a gallium oxide single crystal according to one embodiment of the present invention; and

FIG. 5 shows a graph of the measurement of the loss rate of iridium per one gallium oxide single crystal-producing process in an iridium crucible according to the partial pressure of carbon dioxide in the air.

### DETAILED DESCRIPTION OF EXEMPLARY EMBODIMENTS

Hereinafter, with reference to the accompanying drawings, embodiments of the present invention will be described in detail so that those skilled in the art can easily implement them. However, the present invention may be embodied in many different forms and is not limited to the embodiments set forth herein. In order to clearly illustrate the present application in the drawings, parts irrelevant to the description are omitted, and the same reference numerals are given to the same or similar parts throughout the specification.

Throughout the specification, when a part is “connected” to another part, this includes not only the case where it is “directly connected” but also the case where it is “indirectly connected” with another member or element interposed therebetween. In addition, when a part is said to “include” a component, this means that the component may further include other components, rather than excluding other components, unless specifically stated to the contrary. In addition, when a component is expressed in the singular, the plural is included unless specifically stated otherwise.

The shapes, sizes, ratios, angles, numbers, and the like disclosed in the drawings for explaining embodiments of the present invention are illustrative, and the present invention is not limited to the matters shown. In addition, in the description of the present invention, when it is determined that a specific description of a related known technology may unnecessarily obscure the subject matter of the present invention, the detailed description will be omitted. When interpreting components, it is interpreted to include the error ranges even when there is no separate explicit description.

Although “first,” “second,” etc. are used to describe various components, these components are not limited by these terms. These terms are merely used to distinguish one component from another. Therefore, the first component mentioned below may also be the second component within the technical spirit of the present invention.

Each feature of the various embodiments of the present invention can be partially or entirely coupled or combined with each other, can be technically linked and operated in various ways as can be fully understood by those skilled in the art, and each embodiment can be implemented independently of each other or can be implemented together in a related relationship.

Meanwhile, the tentative effects that can be expected by the technical features of the present invention that are not specifically mentioned in the specification of the present invention are treated as described in the specification, and since these embodiments are provided to more completely explain the present invention to a person with average knowledge in the art, the contents depicted in the drawings can be expressed in an exaggerated manner compared to the actual implementation of the invention, and detailed descriptions of the configurations that are judged to unnecessarily obscure the subject matter of the present invention are omitted or briefly described.

Hereinafter, the present invention will be described in detail with reference to the accompanying drawings.

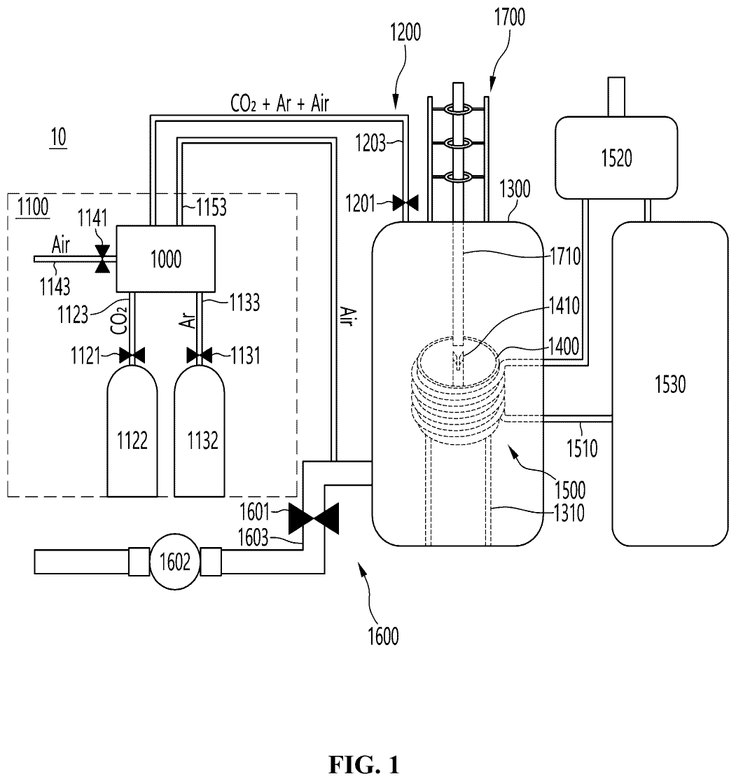

FIG. 1 shows a view for describing an apparatus for growing a single crystal according to one embodiment of the present invention.

Referring to FIG. 1, an apparatus 10 for growing a single crystal according to one embodiment of the present invention includes a crucible 1400, a heating device 1500 for heating the crucible 1400, a chamber 1300 for accommodating the crucible 1400, an injection unit 1200 for injecting carbon dioxide into the chamber 1300, and a control unit 1000 for controlling the partial pressure of the injected carbon dioxide.

The crucible 1400 according to one embodiment of the present invention is a heating container that may charge and melt provided raw materials and that may store the resulting melt. Therefore, the crucible 1400 may be made of a material with high heat resistance and high fire resistance that does not deform or melt even at the melting point of the charged raw material.

The main raw material of the crucible 1400 according to one embodiment of the present invention may be iridium. Preferably, a crucible 1400 made only of iridium may be used.

The apparatus 10 for growing a single crystal according to one embodiment may additionally include a die 1410 inside the crucible 1400, and may further include a slit inside the die 1410 that communicates with the internal space of the crucible 1400.

The slit raises the melt to induce growth into a single crystal, and the cross-sectional shape of the slit may correspond to the cross-sectional shape of the final produced single crystal.

The die 1410 constitutes the outer wall of the slit and may be formed with an appropriate thickness to prevent leakage and evaporation of the melt raised by the slit. The main raw material of the die 1410 may be iridium.

The heating device 1500 according to one embodiment of the present invention is a device that may heat the raw material provided in the crucible 1400 to melt it. As the heating device 1500, a resistance heating device, an induction heating device, a laser heating device, an electron beam heating device, an arc heating device may be used, and depending on the heating device, it may be provided outside the crucible 1400, or part or all of the heating device may be placed inside the crucible 1400. Preferably, an induction heating device 1500 may be used, and the induction heating device 1500 may be provided outside the crucible 1400.

The heating device 1500 according to one embodiment of the present invention is an induction heating device 1500, which may include a coil 1510, a power inverter 1520, and a temperature control device 1530.

The coil 1510 consists of a wire and is a device that has inductance by winding the wire in a cylindrical or annular shape. The wire constituting the coil 1510 includes a conductor through which current can flow. In addition, since the coil 1510 according to one embodiment of the present invention should maintain its performance stably even in a high-temperature process environment, a conductive material with heat resistance may be selected and used.

The power inverter 1520 according to one embodiment of the present invention is an electrical conversion device for changing direct current (DC) components into alternating current (AC) components. The power inverter 1520 may convert external current into alternating current of an appropriate frequency and apply it to the coil 1510.

The temperature control device 1530 according to one embodiment of the present invention is a device that may control the degree of heating of the metal material surrounding the coil 1510 by controlling the current flowing through the coil 1510.

The induction heating device 1500 according to one embodiment of the present invention may heat a metal object using electromagnetic induction. Specifically, when external power is supplied to the coil 1510 as an AC current of an appropriate frequency through the power inverter 1520, the magnetic field changes due to the change in the current flowing in the coil 1510, and accordingly, an induced electromotive force is generated inside the metal surrounding the coil 1510, so that eddy currents can flow. At this time, Joule heating generated by the resistance of the metal can increase the temperature of the metal.

Based on the above-described principle, the induction heating device 1500 according to one embodiment of the present invention may increase the temperature of the crucible 1400 by heating the metal contained in the crucible 1400 surrounded by the coil 1510.

In addition, the temperature control device 1530 according to one embodiment of the present invention may control the temperature of the crucible 1400 and the internal environment of the crucible 1400 by controlling the current flowing through the coil 1510. For example, the temperature control device 1530 according to one embodiment of the present invention may maintain the temperature of the internal environment of the crucible 1400 at a temperature higher than the melting point of the raw material charged into the crucible 1400.

The chamber 1300 according to one embodiment of the present invention is a container that may accommodate a high temperature object, may accommodate the crucible 1400 and the coil 1510 wound around the crucible 1400, and include an opening for the coil 1510 to be connected to the outside

In addition, the chamber 1300 according to one embodiment of the present invention may include a refractory material that may withstand high temperatures.

The refractory material is a material that has heat resistance and chemical stability, and may be included in the chamber 1300 to prevent the chamber 1300 from being deformed or melted even when a high-temperature environment is formed within the chamber 1300. The type of refractory material is not limited as long as it can prevent deformation and melting of the chamber 1300. For example, as the refractory material, silicon carbide (SiC), zirconia (ZrO₂, zirconium dioxide), alumina (Al₂O₃, aluminum oxide), silicon nitride (Si₃N₄), tungsten (W), molybdenum (Mo), which maintain physical and chemical stability even in high-temperature environments, may be used. Preferably, zirconia or alumina may be used.

In addition, the chamber 1300 according to one embodiment of the present invention may include a crucible support 1310 for supporting and fixing the crucible 1400.

The crucible support 1310 according to one embodiment of the present invention interconnects and fixes the inner wall of the chamber 1300 and the crucible 1400, and during the process, unnecessary movements of the crucible 1400 and the contents charged into the crucible 1400 may be minimized. The specific shape of the crucible support 1310 is not limited as long as it may stably support and fix the crucible 1400. However, the crucible support 1310 should not be deformed or melted even in a high-temperature environment within the chamber 1300, and thus the crucible support 1310 according to one embodiment of the present invention may include a refractory material.

The chamber 1300 including the above-described refractory material and the crucible support 1310 included in the chamber 1300 can stably store and support the crucible 1400 even in a high-temperature environment, and thus the single crystal producing process may proceed stably.

The chamber 1300 according to one embodiment of the present invention may be composed of a partition wall that blocks unnecessary materials and energy from entering and exiting between the inside and outside of the chamber 1300, except for openings provided for specific purposes, such as an opening for connecting the above-described coil 1510 to the outside. As a result, the environment, such as temperature, air pressure, and partial pressure of each gas, inside the chamber 1300 may be smoothly controlled.

The control unit 1000 according to one embodiment of the present invention is a control device that may control the partial pressure of carbon dioxide injected into the chamber 1300. In addition, the control unit 1000 according to one embodiment of the present invention may control the partial pressure of each gas injected into the chamber 1300 in addition to carbon dioxide.

Specifically, the control unit 1000 according to one embodiment of the present invention may control the injection pressure of each gas injected into the chamber 1300, and thus may control the partial pressure of each gas within the chamber 1300.

The control unit 1000 according to one embodiment of the present invention may include a mass flow controller (MFC) 1000.

The MFC 1000 according to one embodiment of the present invention is a device that may measure and precisely control the flow rate of gas, and may include an inlet port, an inner passage, an outlet port, a sensor, a comparator, control algorithm, an actuator, and a valve. In addition, in order for the MFC 1000 according to an embodiment of the present invention to control the flow rate of gas flowing in the inner passage, a separate gas supply device may be connected to the MFC 1000, and the connected gas supply device may inject gas into the inner passage through the valve of the MFC 1000.

When gas flows into the inner passage through the inlet port of the MFC 1000 according to one embodiment of the present invention, the sensor of the MFC 1000 may measure the flow rate of the corresponding gas. The measured flow rate information may be compared with the target flow rate of the corresponding gas through the comparator of the MFC 1000. When a difference from the target flow rate is found, the control value of the valve is determined according to the control algorithm of the MFC 1000, and the actuator of the MFC 1000 may control the valve according to the determined control value. As a result, gas may be properly injected into the inner passage from the gas supply device connected to the MFC 1000, and the flow rate of gas flowing in the inner passage may be controlled. Gas with a controlled flow rate may be provided by being discharged through the outlet port of the MFC 1000.

The apparatus 10 for growing a single crystal according to one embodiment of the present invention may further include a gas supply unit 1100 connected to the control unit 1000.

The gas supply unit 1100 according to one embodiment of the present invention is a gas supply source capable of supplying gas required for the control unit 1000, and may function as a gas supply device connected to the MFC 1000 described above.

The gas supply unit 1100 according to one embodiment of the present invention may include a first air pipe 1143, an air valve 1141, a carbon dioxide storage container 1122, a carbon dioxide pipe 1123, and a carbon dioxide valve 1121. In addition, the gas supply unit 1100 according to one embodiment of the present invention may further include an argon storage container 1132, an argon pipe 1133, and an argon valve 1131.

The first air pipe 1143 according to one embodiment of the present invention is a pipe that communicates with the outside and the control unit 1000 and may deliver external air to the control unit 1000. The air valve 1141 according to one embodiment of the present invention is a valve that is provided in the first air pipe 1143 and may be used to control the flow rate of air delivered through the first air pipe 1143.

The carbon dioxide storage container 1122 according to one embodiment of the present invention is a container that may stably store and supply carbon dioxide. The carbon dioxide pipe 1123 according to one embodiment of the present invention is a pipe that communicates with the carbon dioxide storage container 1122 and the control unit 1000 and may deliver carbon dioxide from the carbon dioxide storage container 1122 to the control unit 1000. The carbon dioxide valve 1121 according to one embodiment of the present invention is a valve that is provided in the carbon dioxide pipe 1123 and may be used to control the flow rate of carbon dioxide delivered through the carbon dioxide pipe 1123.

The argon storage container 1132 according to one embodiment of the present invention is a container that may stably store and supply argon. The argon pipe 1133 according to one embodiment of the present invention is a pipe that communicates with the argon storage container 1132 and the control unit 1000 and may deliver argon from the argon storage container 1132 to the control unit 1000. The argon valve 1131 according to one embodiment of the present invention is a valve that is provided in the argon pipe 1133 and may be used to control the flow rate of argon delivered through the argon pipe 1133.

When the above-described gas supply unit 1100 supplies external air, carbon dioxide, and argon to the control unit 1000, the control unit 1000 according to an embodiment of the present invention may precisely control the flow rate of each gas as described above, and may precisely control the injection pressure of each gas injected into the chamber 1300 and the partial pressure of each gas within the chamber 1300.

The gas provided to the injection unit 1200 through the control unit 1000 according to one embodiment of the present invention may be single gas or mixed gas, and in this specification, the gas provided to the injection unit 1200 through the control unit 1000 is collectively referred to as mixed gas for convenience. Specifically, the mixed gas provided to the injection unit 1200 through the control unit 1000 according to one embodiment of the present invention may include at least one of the carbon dioxide, argon, and external air described above.

The injection unit 1200 according to one embodiment of the present invention is a device that interconnects the control unit 1000 and the chamber 1300, and may inject the mixed gas provided through the control unit 1000 into the chamber 1300.

The injection unit 1200 according to one embodiment of the present invention may include a mixed gas pipe 1203 and a mixed gas valve 1201.

The mixed gas pipe 1203 according to one embodiment of the present invention is a pipe that communicates with the control unit 1000 and the chamber 1300 and may inject the mixed gas provided through the control unit 1000 into the chamber 1300. The mixed gas valve 1201 according to one embodiment of the present invention is a valve that is provided in the mixed gas pipe 1203 and may be used to control the flow rate of the mixed gas delivered through the mixed gas pipe 1203.

The mixed gas provided through the control unit 1000 according to one embodiment of the present invention may be injected into the chamber 1300 through the above-described injection unit 1200, and thus the injection pressure of each gas constituting the mixed gas and the partial pressure of each gas within the chamber 1300 may be precisely controlled by the control unit 1000.

Meanwhile, as shown in FIG. 1, the apparatus 10 for growing a single crystal according to one embodiment of the present invention may further include an air pressure control device 1600, and the air pressure control device 1600 may include a throttle valve 1601, a rotary vane pump 1602, and a third air pipe 1603.

In this case, the gas supply unit 1100 according to one embodiment of the present invention may further include a second air pipe 1153 that interconnects the control unit 1000 and the third air pipe 1603. The second air pipe 1153 according to one embodiment of the present invention is a pipe that is capable of delivering external air provided through the control unit 1000 to the third air pipe 1603.

The air pressure control device 1600 according to one embodiment of the present invention is a device capable of controlling the pressure of air in the chamber 1300. At this time, the air pressure refers to the total pressure corresponding to the sum of the partial pressures of each gas present in the chamber 1300.

The third air pipe 1603 according to one embodiment of the present invention is a pipe that communicates with the second air pipe 1153, the rotary vane pump 1602, and the chamber 1300 and may deliver external air provided through the second air pipe 1153 and the air inside the chamber 1300 to the rotary vane pump 1602 through the throttle valve 1601.

The throttle valve 1601 according to one embodiment of the present invention is a valve that is provided in the third air pipe 1603 and may be used to control the flow rate of the above-described air delivered through the third air pipe 1603.

The rotary vane pump 1602 according to one embodiment of the present invention is a device that may suck the above-described air from the third air pipe 1603 and discharge it to the outside.

The air in the chamber 1300 according to one embodiment of the present invention and the external air provided through the second air pipe 1153 may be discharged to the outside with the flow rate controlled by the throttle valve 1601, and thus allows the air pressure in the above-described chamber 1300 to be precisely controlled by the throttle valve 1601. For example, the throttle valve 1601 according to one embodiment of the present invention may control the air pressure in the chamber 1300 to be more than 1 bar and less than 1.4 bar.

Meanwhile, as shown in FIG. 1, the apparatus 10 for growing a single crystal according to one embodiment of the present invention may further include a seed crystal lifting and lowering device 1700 for growing a single crystal, and the seed crystal lifting and lowering device 1700 may include a seed crystal support 1710 and a power unit for driving the seed crystal support 1710.

The seed crystals are structures that are introduced into a melt to initiate single crystal growth in the single crystal growth process. When one surface of the seed crystal is introduced into the melt, the crystallinity of the seed crystal is delivered to the melt and at the same time the melt solidifies to form a single crystal. As the melt adjacent to the single crystal thus formed solidifies as the seed crystal rises and the single crystal is repeatedly extended, a single crystal may be produced on one surface of the seed crystal.

As described above, since the seed crystal should be introduced into the melt, it may be placed inside the chamber 1300 according to one embodiment of the present invention.

The seed crystal raising and lowering device 1700 according to one embodiment of the present invention is a power source that may control the up and down movement of the seed crystal.

The seed crystal support 1710 according to one embodiment of the present invention is a structure provided to support the seed crystal inside the chamber 1300 by passing through the partition wall of the chamber 1300. The seed crystal support 1710 according to one embodiment of the present invention may stably support the seed crystal and prevent the seed crystal from detaching or falling into the melt. In addition, the seed crystal support 1710 according to one embodiment of the present invention transmits power from the above-described power unit to the seed crystal so that the seed crystal is raised or lowered according to the control of the seed crystal raising and lowering device 1700 and may maintain the above-described stability despite the movement of the seed crystal.

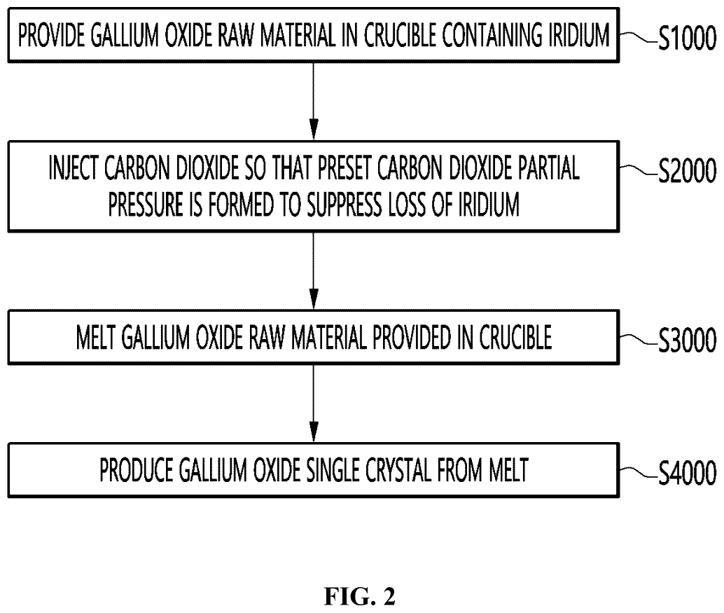

Hereinafter, a method for growing a gallium oxide single crystal using an apparatus for growing a single crystal according to one embodiment of the present invention will be described referring to FIG. 2. The method for growing a gallium oxide single crystal may be performed using the apparatus 10 for growing a single crystal shown in FIG. 1, and in explaining the method for growing a gallium oxide single crystal of FIG. 2, FIG. 1 will also be referred to.

FIG. 2 shows a flowchart for explaining a method for growing a gallium oxide single crystal according to one embodiment of the present invention.

Referring to FIG. 2, the method for growing a gallium oxide single crystal according to one embodiment of the present invention includes providing a gallium oxide raw material in a crucible 1400 containing iridium (S1000), injecting carbon dioxide so that a preset carbon dioxide partial pressure is formed to suppress the loss of iridium (S2000), melting the gallium oxide raw material provided in the crucible 1400 (S3000), and producing a gallium oxide single crystal from the melt (S4000).

The providing of a gallium oxide raw material in the crucible 1400 containing iridium according to one embodiment of the present invention (S1000) is a process of charging the gallium oxide raw material into the crucible 1400.

The gallium oxide raw material according to one embodiment of the present invention is a raw material having gallium (III) oxide (Ga₂O₃) as a main raw material, and is a raw material for producing a gallium oxide single crystal by being melted in the crucible 1400.

The gallium (III) oxide may consist of an a phase, a β phase, a γ phase, a δ phase, or an ε phase. Preferably, the gallium (III) oxide may be the β phase.

The gallium oxide raw material and the gallium oxide single crystal according to one embodiment of the present invention may consist of only gallium oxide or may further include impurities.

The form and whether or not the gallium oxide raw material is pre-processed according to one embodiment of the present invention are not limited within the range that may be melted by the heating device 1500. For example, the gallium oxide raw material may be in various shapes such as spherical, cylindrical, or cubic shapes, and may be in an unprocessed powder state or a processed sintered body.

The injecting of carbon dioxide so that a preset carbon dioxide partial pressure is formed to suppress the loss of iridium according to one embodiment of the present invention (S2000) is a process of controlling the partial pressure of carbon dioxide around the crucible 1400 to a preset partial pressure to prevent loss of iridium contained in the crucible 1400. The preset partial pressure of carbon dioxide described above is the partial pressure of carbon dioxide that creates an environment in which iridium loss is suppressed, and a detailed description of this will be described later.

In the injecting of carbon dioxide according to one embodiment of the present invention (S2000), carbon dioxide provided through the control unit 1000 according to one embodiment of the present invention may be injected into the chamber 1300 through the injection unit 1200.

The injecting of carbon dioxide according to one embodiment of the present invention (S2000) may include injecting carbon dioxide at a pressure of less than 2.4 bar. For example, the control unit 1000 may control the injection pressure of carbon dioxide according to the operating method of the control unit 1000 described above so that the injection unit 1200 injects carbon dioxide into the chamber 1300 at a pressure of less than 2.4 bar.

The injecting of carbon dioxide according to one embodiment of the present invention (S2000) may include injecting argon. For example, argon provided through the control unit 1000 according to one embodiment of the present invention may be injected into the chamber 1300 together with carbon dioxide through the injection unit 1200, and the injection pressure of argon and the partial pressure of argon in the chamber 1300 may be precisely controlled by the control unit 1000.

The injecting of argon according to one embodiment of the present invention may include injecting the argon at a pressure of less than 4.5 bar. Specifically, the control unit 1000 may control the injection pressure of argon according to the operating method of the control unit 1000 described above so that the injection unit 1200 injects argon into the chamber 1300 at a pressure of less than 4.5 bar.

Hereinafter, the above-described preset partial pressure of the carbon dioxide will be described in detail.

Gallium oxide melts at a high temperature of 1700° C. or higher, and in such a high-temperature environment, the oxidation of iridium occurs more easily than in a low-temperature environment, and the oxidation of iridium tends to proceed more actively in an environment with a higher oxygen partial pressure. When the oxidation of iridium actively progresses, loss of iridium may occur.

However, when the oxygen partial pressure is lowered in a high-temperature environment, gallium (III) oxide may be reduced to gaseous gallium (I) oxide (Ga₂O) or liquid gallium (Ga) due to a thermal decomposition reaction, and when the produced gallium reacts with iridium to form an iridium-gallium alloy, loss of iridium may occur. In addition, the growth of gallium oxide single crystals based on gallium oxide raw materials may also be inhibited.

Therefore, there may be limitations in preventing the loss of iridium by controlling only the oxygen partial pressure.

Thermodynamically, when the partial pressure of gallium (I) oxide gas is high, the above-described reduction of gallium (III) oxide to gallium through thermal decomposition can actively proceed, and thus the partial pressure of oxygen may also increase, and the loss of iridium may also significantly increase due to both the formation of the above-described iridium-gallium alloy and the oxidation of iridium. In addition, as described above, the growth of gallium oxide single crystals may be suppressed due to thermal decomposition of gallium (III) oxide. Therefore, it may be necessary to lower the partial pressure of gallium (I) oxide gas.

The partial pressure of gallium (I) oxide gas may be lowered by controlling the partial pressure of carbon dioxide or argon. Therefore, the loss of iridium may be prevented by controlling the partial pressure of carbon dioxide or argon near iridium through the method for growing a gallium oxide single crystal and the apparatus 10 for growing the single crystal according to one embodiment of the present invention.

For example, the partial pressure of carbon dioxide may be controlled to lower the partial pressure of gallium (I) oxide gas. To this end, the partial pressure of carbon dioxide suitable for minimizing the loss of iridium may be determined. The partial pressure of carbon dioxide that creates an environment in which iridium loss is suppressed is the preset partial pressure of carbon dioxide described above.

In the injecting of carbon dioxide according to one embodiment of the present invention (S2000), the above-described preset partial pressure of carbon dioxide may be 40% or more and 60% or less. In addition, the partial pressure of carbon dioxide injected into the chamber 1300 can be controlled by the control unit 1000 according to an embodiment of the present invention so that the partial pressure of carbon dioxide in the chamber 1300 is 40% or more and 60% or less.

In addition, in the method for growing a gallium oxide single crystal according to one embodiment of the present invention, the throttle valve 1601 according to one embodiment of the present invention may control the air pressure in the chamber 1300 to be more than 1 bar and less than 1.4 bar. For example, the throttle valve 1601 according to an embodiment of the present invention may be precisely controlled so that the pressure of air within the chamber 1300 is maintained constant within a range of 1 atm or more and 1.3 atm or less regardless of the temperature within the chamber 1300.

As a result, thermodynamically, the partial pressure of gallium (I) oxide gas may be lowered. Accordingly, as described above, the loss of iridium may be suppressed, and the phenomenon of inhibiting the growth of gallium oxide single crystals due to thermal decomposition of gallium (III) oxide may also be improved.

The melting of the gallium oxide raw material provided in the crucible 1400 according to one embodiment of the present invention (S3000) is a process of forming a melt by liquefying the above-described gallium oxide raw material charged into the crucible 1400 in a high-temperature environment.

The melting of the gallium oxide raw material according to one embodiment of the present invention (S3000) may be performed by maintaining the internal environment of the crucible 1400 at a higher temperature than the melting point of the gallium oxide raw material. In this case, the heating time may be determined considering the composition, total amount, and heat of melting of the gallium oxide raw material, the efficiency of the heating device, and the like.

In the melting of the gallium oxide raw material according to one embodiment of the present invention (S3000), methods such as resistance heating, induction heating, laser heating, electron beam heating, and arc heating may be used as a method of heating the gallium oxide raw material. Preferably, induction heating may be used. For example, the induction heating device 1500 described above may be used.

The producing of the gallium oxide single crystal from the melt according to one embodiment of the present invention (S4000) is a process of growing the gallium oxide single crystal from the melt formed in the melting of the gallium oxide raw material (S3000).

The producing of the gallium oxide single crystal according to one embodiment of the present invention (S4000) may be performed by solidifying the melt to produce the gallium oxide single crystal. For example, as described above, when a seed crystal is introduced into the melt and rises, the gallium oxide single crystal formed by solidifying the melt on one surface of the seed crystal may grow.

The producing of the gallium oxide single crystal according to one embodiment of the present invention (S4000) may include producing the gallium oxide single crystal from the melt through any one of EFG and CZ growth methods.

As described above, the method for producing the gallium oxide single crystal by solidifying the melt includes crystal growth methods such as EFG and CZ, and in this specification, the single crystal growth method by the EFG method is exemplarily described. However, the method for growing a gallium oxide single crystal and the apparatus 10 for growing the single crystal according to one embodiment of the present invention are not only applicable to the EFG method, but may also be implemented and utilized in the CZ method.

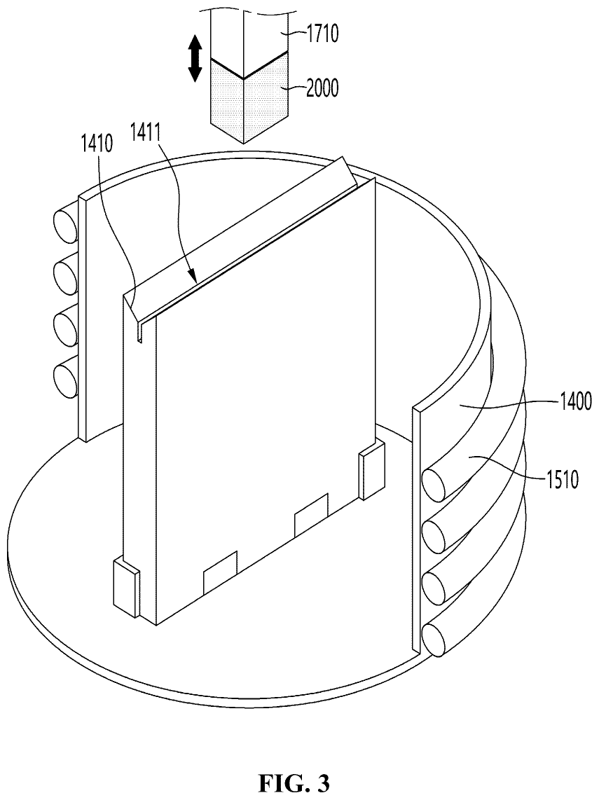

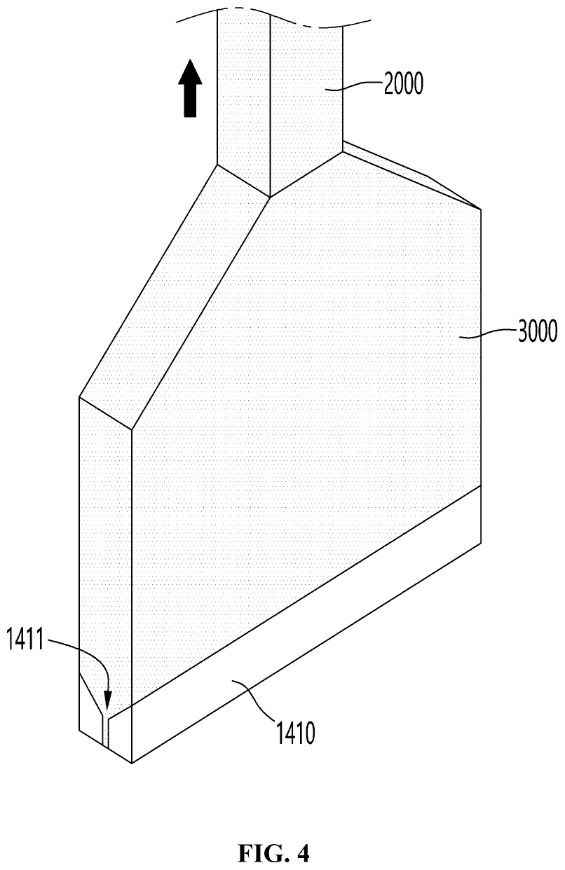

FIG. 3 shows a partial cutaway perspective view for explaining the internal structure of a crucible according to one embodiment of the present invention. FIG. 4 shows a perspective view for explaining the step of producing a gallium oxide single crystal according to one embodiment of the present invention.

Referring to FIGS. 3 and 4, EFG according to one embodiment of the present invention may be performed by allowing a melt in a crucible 1400 to flow into a slit 1411 in a die 1410 inside the crucible 1400, and allowing the melt to rise to the top of the slit 1411 by capillary action and come into contact with the lower surface of a seed crystal 2000, and as the seed crystal 2000 rises, the melt may grow into a gallium oxide single crystal 3000 having the same crystallographic plane as the lower surface of the seed crystal 2000.

At this time, the contact between the seed crystal 2000 and the melt may be achieved by arranging the seed crystal 2000 so that the main surface that gives the single crystal 3000 the target characteristics is parallel to the outer wall of the slit 1411, and bringing the lower surface of the seed crystal 2000 into contact with the melt when considering the composition, size, and the like of the single crystal 3000.

In addition, during the process of allowing the seed crystal 2000 to rise, the rising speed of the seed crystal 2000 may be determined within a range that allows the single crystal 3000 to be produced stably and efficiently. When the rising speed of the seed crystal 2000 is too fast and is outside the above-described range, there may be defects in the final produced single crystal 3000. When the rising speed of the seed crystal 2000 is too slow and is outside the above-described range, the production efficiency of the single crystal 3000 may be reduced.

For example, when the single crystal 3000 to be finally produced is a β-Ga₂O₃ single crystal 3000, the rising speed of the seed crystal 2000 may be determined within the range of 5 mm to 20 mm per hour. Preferably, the seed crystal 2000 may rise at a speed of about 10 mm per hour.

In addition, even within the above-described range regarding the rising speed of the seed crystal 2000, the rising speed of the seed crystal 2000 may be maintained constant or may be changed. Accordingly, the width of the produced single crystal 3000 may be controlled.

In addition, during the process of allowing the seed crystal 2000 to rise, the seed crystal lifting and lowering device 1700 according to one embodiment of the present invention may maintain the direction of the seed crystal 2000 constant, or may also change the orientation of the single crystal 3000 being formed by changing the direction of the seed crystal 2000.

The mass of the gallium oxide single crystal 3000 produced in the step (S4000) of producing the gallium oxide single crystal 3000 according to one embodiment of the present invention may be 90% or more of the mass of the gallium oxide raw material provided in the step (S1000) of providing the gallium oxide raw material.

In addition, after the method for growing a gallium oxide single crystal according to one embodiment of the present invention is performed once, the mass of the gallium oxide raw material remaining in the crucible 1400 may be less than 10% of the mass of the entire gallium oxide raw material provided to the crucible 1400 in the step (S1000) of providing the gallium oxide raw material.

At this time, as described above, the ratio of the mass of the produced gallium oxide single crystal 3000 to the mass of the gallium oxide raw material initially provided is simply referred to in this specification as the raw material-to-crystal conversion rate.

In the step (S4000) of producing the gallium oxide single crystal according to one embodiment of the present invention, the melt rises to the top of the slit 1411 by capillary action, and the rising melt comes into contact with the seed crystal 2000 or the gallium oxide single crystal 3000 produced on one surface of the seed crystal 2000, and the viscosity of the melt at the contact surface may be maintained constant. Accordingly, 90% or more of the entire melt formed in the step (S3000) of melting the gallium oxide raw material may grow into the gallium oxide single crystal 3000, and the raw material-to-crystal conversion rate may be increased.

As described above, the method for growing a gallium oxide single crystal and the apparatus 10 for growing a single crystal according to one embodiment of the present invention improve the efficiency of the process and the productivity of the gallium oxide single crystal 3000 by increasing the raw material-to-crystal conversion rate.

In addition, after the method for growing a gallium oxide single crystal according to one embodiment of the present invention is performed once, a mass of the solid iridium metal contained in the crucible 1400 may be 99.75% or more of the mass of the solid iridium metal contained in the crucible 1400 before the one-time performance. That is, the loss rate of iridium per one-time performance of the above-described process may be 0.25% or less.

Hereinafter, the present invention will be described in more detail through Experimental Examples to explain the effect of the method for growing a gallium oxide single crystal and the apparatus for growing a single crystal.

However, the following Experimental Examples only illustrate the present invention, and the present invention is not limited to the following Experimental Examples.

### (Experimental Example 1)—Confirmation of Conditions for Minimizing Iridium Loss Rate Through CO₂ Partial Pressure Control

In order to compare and evaluate how much the loss rate of iridium is reduced by the method for growing a gallium oxide single crystal and the apparatus for growing a single crystal of the present invention, the following carbon dioxide partial pressure conditions were applied.

TABLE 1

| | Experimental | Experimental | Experimental | Experimental | Experimental |
|---|---|---|---|---|---|
| Classification | Example 1-1 | Example 1-2 | Example 1-3 | Example 1-4 | Example 1-5 |
| CO₂ partial | 40 | 50 | 60 | 70 | 80 |
| pressure (%) | | | | | |

After each single crystal was grown once under the carbon dioxide partial pressure conditions described above, the loss rate of iridium was calculated by measuring the change in mass of the iridium crucible used for single crystal growth. Specifically, the loss rate of iridium was calculated by dividing the lost mass of iridium by the total mass of iridium prior to the single crystal growth. As a result of actual measurements, the calculated loss rate of iridium is shown in [Table 2] below.

TABLE 2

| | Experimental | Experimental | Experimental | Experimental | Experimental |
|---|---|---|---|---|---|
| Classification | Example 1-1 | Example 1-2 | Example 1-3 | Example 1-4 | Example 1-5 |
| CO₂ partial | 40 | 50 | 60 | 70 | 80 |
| pressure (%) | | | | | |
| Loss rate of | 0.11 | 0.07 | 0.25 | 0.34 | 0.13 |
| iridium (%) | | | | | |

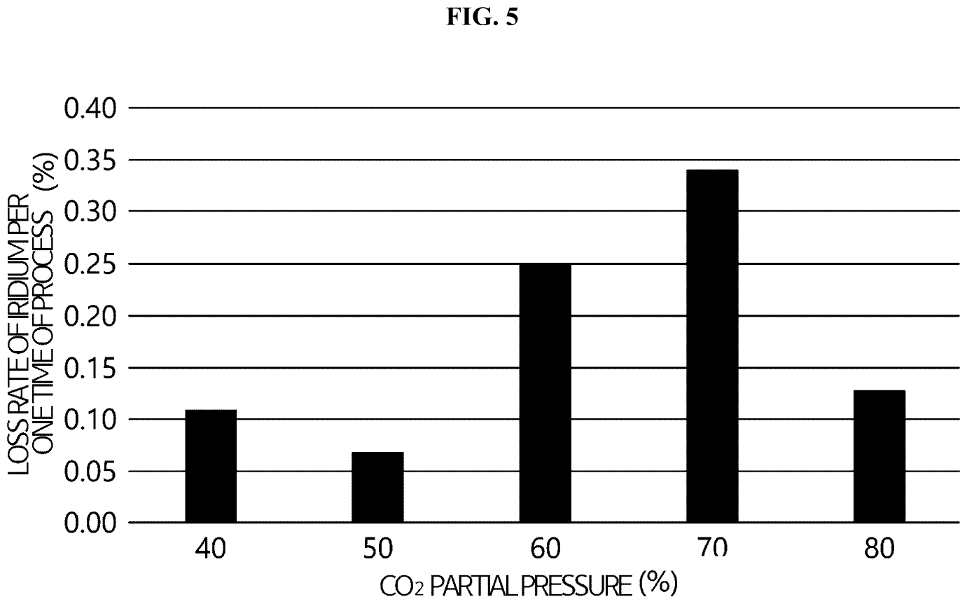

In addition, FIG. 5 shows a graph of the measurement of the iridium loss rate per one gallium oxide single crystal-producing process in an iridium crucible according to the partial pressure of carbon dioxide in the air.

Referring to [Table 2] and FIG. 5, it may be confirmed from the actual measurement results that when the partial pressure of carbon dioxide is 40% to 60%, the loss rate of iridium is suppressed to 0.25% or less.

Meanwhile, in this Experimental Example 1, it was confirmed that the raw material-to-crystal conversion rate in the process of producing the gallium oxide single crystal was 90% or more.

The method for growing a gallium oxide single crystal and the apparatus for growing a single crystal of the present invention have the effect of thermodynamically minimizing the loss of iridium metal contained in the iridium crucible by precisely controlling the partial pressure of each gas and the total air pressure around the iridium crucible.

In addition, the method for growing a gallium oxide single crystal and the apparatus for growing a single crystal of the present invention have the effect of improving the growth inhibition phenomenon of a gallium oxide single crystal caused by thermal decomposition of gallium (III) oxide in thermodynamic terms by precisely controlling the partial pressure of each gas around the iridium crucible and the pressure of the entire air.

In addition, the method for growing a gallium oxide single crystal and the apparatus for growing a single crystal of the present invention have the effect of increasing the raw material-to-crystal conversion rate to 90% or more.

In addition, the method for growing a gallium oxide single crystal and the apparatus for growing a single crystal of the present invention have the effect of increasing the efficiency and productivity of the process due to the above-described effects, and have a cost-effective advantage by preventing the loss of iridium metal.

According to one of the above-described means for solving the problems of the present invention, a method for growing a gallium oxide single crystal and an apparatus for growing a single crystal include injecting carbon dioxide so that a preset carbon dioxide partial pressure is formed to suppress the loss of iridium, and the control unit for controlling the partial pressure of the injected carbon dioxide, so that the loss of iridium metal contained in the iridium crucible can be minimized thermodynamically.

In addition, according to one of the means for solving the problems of the present invention, the method for growing a gallium oxide single crystal and the apparatus for growing a single crystal further include a throttle valve, so that the growth inhibition phenomenon of the gallium oxide single crystal can be improved thermodynamically.

In addition, according to one of the means for solving the problems of the present invention, the method for growing a gallium oxide single crystal and the apparatus for growing a single crystal include melting the gallium oxide raw material provided in a crucible and producing a gallium oxide single crystal from the melt, so that the ratio of the mass of the produced gallium oxide single crystal to the mass of the initially provided gallium oxide raw material can be increased to 90% or more.

In addition, according to one of the means for solving the problems of the present invention, the method for growing a gallium oxide single crystal and the apparatus for growing a single crystal of the present invention have the effect of increasing the efficiency and productivity of the process due to the above-described effects, and have a cost-effective advantage by preventing the loss of iridium metal.

The effects obtainable in the present invention are not limited to those mentioned above, and other effects not mentioned may be clearly understood by those skilled in the art from the following description.

The foregoing description of the present invention is intended to be illustrative, and it will be understood by those skilled in the art that embodiments may be easily modified into other specific forms without changing the spirit and essential characteristics of the invention. Therefore, it should be understood that the embodiments described above are illustrative in all respects and not restrictive. For example, each component described as a single type may be implemented in a distributed form, and likewise components described as distributed may be implemented in a combined form.

The scope of the present invention is indicated by the following claims rather than by the above description, and all changes or modifications that come from the meaning and range of the claims and their equivalents should be construed to be included within the scope of the present invention.

What is claimed is:

1. A method for growing a gallium oxide single crystal, comprising:
providing a gallium oxide raw material in a crucible containing iridium;
injecting carbon dioxide so that a preset partial pressure of the carbon dioxide is formed to suppress the loss of the iridium;
melting the gallium oxide raw material provided in the crucible; and
producing a gallium oxide single crystal from the melt.

2. The method of claim 1, wherein the preset partial pressure of the carbon dioxide is 40% or more and 60% or less.

3. The method of claim 1, wherein the injecting of the carbon dioxide includes injecting the carbon dioxide at a pressure of less than 2.4 bar.

4. The method of claim 1, wherein the injecting of the carbon dioxide includes injecting argon.

5. The method of claim 4, wherein the injecting of the argon includes injecting the argon at a pressure of less than 4.5 bar.

6. The method of claim 1, wherein after the single crystal growth method is performed once, a mass of a solid iridium metal contained in the crucible is 99.75% or more of the mass of the solid iridium metal contained in the crucible before the one-time performance.

7. The method of claim 1, wherein a mass of the produced gallium oxide single crystal is 90% or more of the mass of the provided gallium oxide raw material.

8. The method of claim 1, wherein after the single crystal growth method is performed once, a mass of the provided gallium oxide raw material remaining in the crucible is less than 10% of the mass of the gallium oxide raw material provided in the crucible before the one-time performance.

9. The method of claim 1, wherein the producing of the gallium oxide single crystal includes producing the gallium oxide single crystal from the melt through any one of edge-defined film-fed growth (EFG) and Czochralski (CZ) growth.

10. An apparatus for growing a single crystal, comprising:
a crucible
a heating device that heats the crucible;
a chamber in which the crucible is accommodated;
an injection unit that injects carbon dioxide into the chamber; and
a control unit that controls a partial pressure of the injected carbon dioxide.

11. The apparatus of claim 10, wherein the control unit controls the partial pressure of the injected carbon dioxide so that the partial pressure of the carbon dioxide in the chamber is 40% or more and 60% or less.

12. The apparatus of claim 10, wherein the injection unit injects the carbon dioxide into the chamber at a pressure of less than 2.4 bar.

13. The apparatus of claim 10, wherein the injection unit injects argon into the chamber at a pressure of less than 4.5 bar.

14. The apparatus of claim 10, further comprising a throttle valve.

15. The apparatus of claim 14, wherein the throttle valve controls an air pressure in the chamber to be more than 1 bar and less than 1.4 bar.

16. The apparatus of claim 10, further comprising a seed crystal lifting and lowering device for growing the single crystal.

17. The apparatus of claim 10, wherein the chamber includes a refractory material capable of withstanding high temperatures.

18. The apparatus of claim 10, wherein a main raw material of the crucible is iridium.

19. The apparatus of claim 10, further comprising a die inside the crucible, and a slit inside the die that communicates with an internal space of the crucible.

20. The apparatus of claim 19, wherein a main raw material of the die is iridium.
